(19) United States
(12) Patent Application Publication
(10) Pub. No.: US 2022/0153627 A1
(43) Pub. Date: May 19, 2022

(54) GLASS POWDER AND SILVER-ALUMINUM PASTE FOR USE ON FRONT OF N-TYPE DOUBLE-SIDED SOLAR CELL COMPRISING SAME

(71) Applicant: NANTONG T-SUN NEW ENERGY CO., LTD., Jiangsu (CN)

(72) Inventors: Peng ZHU, Jiangsu (CN); Saijie SHI, Jiangsu (CN); Jinhua ZHENG, Jiangsu (CN)

(73) Assignee: NANTONG T-SUN NEW ENERGY CO., LTD., Jiangsu (CN)

(21) Appl. No.: 17/439,818

(22) PCT Filed: May 13, 2019
(86) PCT No.: PCT/CN2019/086561

§ 371 Date: Sep. 16, 2021

(30) Foreign Application Priority Data
Apr. 29, 2019 (CN) 201910353963.2

(51) Int. Cl. C03C 3/072; H01L 31/048; C03C 12/00; C22C 5/06; B22F 1/10

(52) U.S. Cl. CPC C03C 3/072; H01L 31/0488; C03C 12/00; B22F 2302/45; B22F 1/10; B22F 2301/255; C22C 5/06

(57) ABSTRACT

The present invention relates to a glass powder and a silver-aluminum paste for use on a front of an N-type double-sided solar cell comprising a conductive silver powder, a silicon-aluminum alloy powder, the glass powder and an organic vehicle. The glass powder comprises the following components by weight: 0-50% of PbO, 0-50% of BiO, 5-15% of B₂O₃, 8-9% of SiO₂, 2-3% of Al₂O₃ and 5-15% of ZnO; silicon and aluminum in the glass powder have a mass ratio of 4:1-5:1; the conductive silver powder has a content of 80-90 wt %; the conductive silver powder comprises a nano-silver powder and a silver alloy powder, and the nano-silver powder to the silver alloy powder have a mass ratio of 1:18-1:90.

### BACKGROUND

### Technical Field

The present invention relates to the field of solar cells, and in particular to a glass powder and a silver-aluminum paste for use on a front of an N-type double-sided solar cell including the same.

### Description of Related Art

Improved conversion efficiency and reduced cost are relentless pursuits in the field of solar cells. Currently, P-type crystalline silicon cells occupy the prominent share of the crystalline silicon cell market. N-type monocrystalline silicon has superiorities of long minority carrier lifetime, less light-induced degradation and the like to the conventional P-type monocrystalline silicon, and thus has a greater possibility of efficiency improvement. In addition, the N-type monocrystalline silicon assembly has advantages such as good sensitivity to weak light and lower temperature coefficient. Therefore, the N-type monocrystalline system has the dual advantages of high power generation capacity and high reliability. With the introduction of new cell technologies and processes, the efficiency advantage of N-type monocrystalline cells becomes more and more considerable, and the market share of N-type monocrystalline cells is expected to increase from about 5% in 2014 to about 35% in 2025. The currently studied high-efficiency N-type monocrystalline cells mainly include: PERT cells, HIT cells and IBC cells, in which PERT cells are highly compatible with existing production lines, and have received close attention from many leading manufacturers and the market. PERT cells are typical double-sided solar cells, which refer to solar cells that can receive light on both sides of a silicon wafer and generate photo-generated voltage and current.

At present, researchers improve the silver-aluminum paste mainly in the following aspects:

(1) To reduce the manufacturing costs of the silver-aluminum paste: The cost of the paste can be reduced by reducing the use of the expensive components in the paste. For example, in the paste prepared according to Chinese Patent No. CN200710042439.0, the expensive silver paste is reduced, which not only reduces the manufacturing costs, but also avoids asynchronous sintering of silver and aluminum and generation of aluminum beads in the processes of printing and sintering, resulting in a good ohmic contact and an improved photoelectric conversion efficiency. However, the silver-aluminum paste prepared according to this technical scheme has a higher sintering temperature, leading to increased recombination on the surface and a reduced photoelectric conversion efficiency.

(2) To improve the photoelectric conversion efficiency of the silver-aluminum paste conductive electrode: Such improvement mainly focuses on aspects such as increasing ohmic contacts, reducing recombination, increasing open-circuit voltage and reducing contact resistance. For example, in the paste prepared according to Chinese Patent No. CN201610264780.X, a silver powder and an aluminum powder are contained as basic conductive metal components, and the aluminum together with the silver serves as a conductive metal powder material; with part of the silver power replaced with the aluminum powder, the cost of the conductive paste is well reduced. Moreover, in the present invention, graphene is added to increase the conductivity of the sintered silver-aluminum paste. However, the use of the aluminum metal powder in the silver-aluminum paste will lead to a higher line resistance when the silver-aluminum paste prepared is printed, thereby resulting in increased series resistance, and the amount of conductive aluminum in the silver-aluminum paste has a greater influence on the line resistance, especially when the line frame of finger printing is less than 30 μm.

(3) To reduce the environmental pollution by the conductive silver-aluminum paste: Such improvement focuses on reducing application of heavy metals such as Pb in the paste. For example, in the paste prepared according to Chinese Patent No. CN201010294275.2, an environment-friendly glass powder free of harmful substances is used as a binder, and environment-friendly organic reagents are used as solvents and diluents; the prepared silver-aluminum paste is free of the six substances (Pb, Cd, Hg, Cr (VI), polybrominated biphenyls (PBBs), and polybrominated diphenyl ethers (PBDEs)) prohibited by the RoHS directive of the European Union, such that the environment is truly protected. However, the paste is not suitable for use as a low temperature-sintering paste, and the glass powder free of Pb is not suitable for sintering of a passivation layer SiNₓ; therefore, the paste does not meet the requirements on low temperature-sintering.

### SUMMARY

Purpose: In order to solve the defects in the prior art, the present invention provides a glass powder and a silver-aluminum paste for use on a front of an N-type double-sided solar cell including the same.

Technical Scheme: The first innovation of the present invention provides a glass powder, including the following components by weight: 0-50% of PbO, 0-50% of BiO, 5-15% of B₂O₃, 8-9% of SiO₂, 2-3% of Al₂O₃ and 5-15% of ZnO, wherein the glass powder has a silicon-to-aluminum mass ratio of 4:1-5:1, and the glass powder further includes 5-15% of an oxide of an element from group IA and 5-15% of an oxide of an element from group IIA.

In some embodiments, the oxide of the element from group IA is prepared from one or more compounds of the element from group IA selected from LiO, K₂O, Na₂O, Cs₂O, Li₂CO₃, K₂CO₃, NaCl and KCl.

In some embodiments, the oxide of the element from group IIA is prepared from one or more compounds of the element from group IIA selected from MgO, CaO, BaO, SrO, CaCO₃, MgCO₃ and BaCO₃.

In some embodiments, the glass powder has a softening temperature of 300-400° C. and an average particle size D50 of 0.5-5 μm.

The second innovation of the present invention provides a silver-aluminum paste for use on a front of an N-type double-sided solar cell, including a conductive silver powder, a silicon-aluminum alloy powder, the glass powder disclosed herein and an organic vehicle, wherein the conductive silver powder has a content of 80-90 wt % and includes a nano-silver powder with an average particle size of 50-100 nm and a silver alloy powder with an average particle size of 1-10 μm; the nano-silver powder and the silver alloy powder have a mass ratio of 1:18-1:90; the glass powder has a content of 5-10 wt %.

In some embodiments, the nano-silver powder has a content of greater than 99.9%, an apparent density of 1.4-1.90 g/cm³, a tap density of 2.6-4.1 g/cm³, and a sheet resistance of 0-0.002 Ω/sq.

In some embodiments, the aluminum-silicon alloy powder has a content of 1-10 wt %, an average particle size of 0.5-5 μm, a melting point of 450-650° C., and a Si mass fraction of 12-25%.

In some embodiments, the aluminum-silicon alloy powder has a melting point of 500-600° C.; the aluminum-silicon alloy powder is at least one of an aluminum-silicon alloy powder having a Si mass fraction of 12%, an aluminum-silicon alloy powder having a Si mass fraction of 20% and an aluminum-silicon alloy powder having a Si mass fraction of 25%.

In some embodiments, the organic vehicle has a content of 5-10 wt %, and includes an organic binder, a surface dispersant and a thixotropic agent; the organic binder includes 1-3 parts by mass of an organic resin and 7-9 parts by mass of an organic solvent.

In some embodiments, the organic resin is one or more selected from ethyl cellulose and butyl cellulose acetate; the organic solvent is one or more selected from terpineol, texanol, butyl carbitol, butyl carbitol acetate and glycerol; the surface dispersant is one or more selected from stearic acid, a stearic acid derivative and an unsaturated fatty acid; the thixotropic agent is one or more selected from a modified hydrogenated castor oil and a polyamide wax.

In some embodiments, the silver-aluminum paste has a sintering temperature of 700-750° C.

Beneficial Effects: The present invention has the following advantages:

(1) The glass powder provided by the present invention has the advantages of low softening temperature, high vitrification degree, good wettability to the passivation layer and silver powder in a melted state, and capability of penetrating through the anti-reflection coating to form a good ohmic contact. In the glass powder of the present invention, oxides of elements from group IA and group IIA are introduced, which facilitates the corrosion of the passivation layer by the glass powder without causing serious metal recombination; in the glass powder of the present invention, elements from group IIIA is introduced to increase doping; in the glass powder of the present invention, the ratio of silicon to aluminum is properly adjusted to improve the viscosity of the glass powder, such that the size of the silver particles is improved and the recombination and contact resistance are reduced.

(2) The present invention provides a silver-aluminum paste including the glass powder, which is a conductive metal prepared from a nano-silver powder and a common silver powder. The addition of the nano-silver powder reduces the contact resistance; in the present invention, a silicon-aluminum alloy is also added, which reduces the precipitation of boron, ensures ohmic contacts and increases the open-circuit voltage.

(3) The silver-aluminum paste of the present invention has a high glass powder content of 5-10 wt %, causing minimized damage to SiNₓ and reduced use of silver in the formula and thus resulting in lowered production costs. This content of the glass powder facilitates the dissolving of silver, reduces the contact resistance, and forms less the recombination centers. Solar cells prepared from such paste have high open-circuit voltage and improved conversion efficiencies.

(4) The aluminum-silicon alloy powder of the present invention has a content of 1-10 wt %, which enables effective aluminum doping on the silver-silicon alloy interface, reduces the contact resistance and bulk resistance, and thus improves the photoelectric conversion efficiency. The aluminum-silicon alloy powder has a particle size of 0.5-5 μm, which not only controls the oxygen content and thus reduces oxidation, but also results in effective aluminum doping on the emission electrode to reduce the contact resistance and enable screen printing with a reduced width.

(5) The silver-aluminum paste prepared according to the present invention has a lower sintering temperature of 700-750° C., at which the recombination on the surface is reduced in the process of sintering, thereby improving the photoelectric conversion efficiency.

### DESCRIPTION OF THE EMBODIMENTS

The technical schemes in the embodiments of the present invention will be clearly and completely described below, for a better understanding of the advantages and features of the present invention by those skilled in the art, and for a more the clearly defined protection scope of the present invention. The described embodiments are only some, but not all, embodiments of the invention. Based on the embodiments of the present invention, all other embodiments obtained by those of ordinary skill in the art without making any creative effort will fall within the protection scope of the present invention.

### Example 1

A glass powder was prepared according to formula A1 in Table 1. PbO, BiO, B₂O₃, SiO₂, Al₂O₃ and ZnO were weighed according to the ratios. The compounds of the elements from group IA contained 5% of Na₂O and 5% of LiO, and the compounds of the elements from group IIA contained 3% of K₂O, 3% of CaO and 4% of BaO. The compounds of the elements from groups IA and IIA were also weighed according to the ratios. The above starting materials of the glass powder were well mixed in a crucible at room temperature. The crucible containing the starting materials of the glass powder was heated in a high temperature-melting furnace to 1100° C. for 1 h for melting into a uniform glass liquid. The glass liquid was subjected to deionized water quenching to form irregular glass flakes. The glass flakes were crushed in a ball mill for 6 h at a rotating speed of 250 r/min. The milled glass powder was sieved with a 200-250 mesh sieve. The sieved glass powder was dried in a dryer at 55° C. for 3 h to give glass powder A1 for use in a silver-aluminum paste. The procedures were repeated three times for each formula to give an average value.

A silver-aluminum paste including the above glass powder for use on a front of an N-type double-sided solar cell was prepared according to formula B1 in Table 2. A nano-silver powder, a silver alloy powder, glass powder A1, the aluminum-silicon alloy powder having a Si mass fraction of 12% and an organic vehicle were weighed according to the ratios, well mixed with a disperser, and milled with a three-roll mill to a particle size of 0.1-1.5 μm to give the silver-aluminum paste B1 for use on the front of a solar cell. The procedures were repeated three times for each formula to give an average value.

### Example 2

A glass powder was prepared according to formula A2 in Table 1. PbO, B₂O₃, SiO₂, Al₂O₃ and ZnO were weighed according to the ratios. The oxides of the elements from group IA contained 5% of LiCl and 5% of Cs₂O, and the compounds of the elements from group IIA contained 5% of K₂O and 5% of CaO. The compounds of the elements from groups IA and IIA were also weighed according to the ratios. The above starting materials of the glass powder were well mixed in a crucible at room temperature. The crucible containing the starting materials of the glass powder was heated in a high temperature-melting furnace to 1100° C. for 1 h for melting into a uniform glass liquid. The glass liquid was subjected to deionized water quenching to form irregular glass flakes. The glass flakes were crushed in a ball mill for 6 h at a rotating speed of 250 r/min. The milled glass powder was sieved with a 200-250 mesh sieve. The sieved glass powder was dried in a dryer at 55° C. for 3 h to give glass powder A2 for use in a silver-aluminum paste. The procedures were repeated three times for each formula to give an average value.

A silver-aluminum paste including the above glass powder for use on a front of an N-type double-sided solar cell was prepared according to formula B2 in Table 2. A nano-silver powder, a silver alloy powder, glass powder A2, the aluminum-silicon alloy powder having a Si mass fraction of 20% and an organic vehicle were weighed according to the ratios, well mixed with a disperser, and milled with a three-roll mill to a particle size of 0.1-1.5 μm to give the silver-aluminum paste B2 for use on the front of a solar cell. The procedures were repeated three times for each formula to give an average value.

### Example 3

A glass powder was prepared according to formula A3 in Table 1. BiO, B₂O₃, SiO₂, Al₂O₃ and ZnO were weighed according to the ratios. The compounds of the elements from group IA contained 5% of K₂O and 5% of Cs₂, and the compounds of the elements from group IIA contained 3% of SrO, 3% of MgCO₃ and 4% of BaO. The compounds of the elements from groups IA and IIA were also weighed according to the ratios. The above starting materials of the glass powder were well mixed in a crucible at room temperature. The crucible containing the starting materials of the glass powder was heated in a high temperature-melting furnace to 1100° C. for 1 h for melting into a uniform glass liquid. The glass liquid was subjected to deionized water quenching to form irregular glass flakes. The glass flakes were crushed in a ball mill for 6 h at a rotating speed of 250 r/min. The milled glass powder was sieved with a 200-250 mesh sieve. The sieved glass powder was dried in a dryer at 55° C. for 3 h to give glass powder A3 for use in a silver-aluminum paste. The procedures were repeated three times for each formula to give an average value.

A silver-aluminum paste including the above glass powder for use on a front of an N-type double-sided solar cell was prepared according to formula B3 in Table 2. A nano-silver powder, a silver alloy powder, glass powder A3, the aluminum-silicon alloy powder having a Si mass fraction of 25% and an organic vehicle were weighed according to the ratios, well mixed with a disperser, and milled with a three-roll mill to a particle size of 0.1-1.5 μm to give the silver-aluminum paste B3 for use on the front of a solar cell. The procedures were repeated three times for each formula to give an average value.

TABLE 1

| Number of | | | | | | | Oxides of elements | Oxides of elements |
|---|---|---|---|---|---|---|---|---|
| glass powder | PbO | BiO | B₂O₃ | SiO₂ | Al₂O₃ | ZnO | from group IA | from group IIA |
| A1 | 25% | 25% | 10% | 8% | 2% | 10% | 10% | 10% |
| A2 | 50% | 0 | 10% | 9% | 2% | 10% | 10% | 10% |
| A3 | 0 | 50% | 10% | 8% | 3% | 10% | 10% | 10% |

TABLE 2

| Number of | Silver | Nano- | | Silicon- | |
|---|---|---|---|---|---|
| silver-aluminum | alloy | silver | Glass | aluminum | Organic |
| paste | powder | powder | powder | alloy powder | vehicle |
| B1 | 80% | 5% | 7.5% | 2.5% | 5% |
| B2 | 86.5% | 1% | 5% | 2.5% | 5% |
| B3 | 82.5% | 2.5% | 7.5% | 2.5% | 5% |

### Test Example 1

The results of performance tests on the glass powders A1, A2 and A3 obtained in Examples 1-3 are shown in Table 3:

TABLE 3

| Number of glass powder | Softening temperature (° C.) |
|---|---|
| A1 | 352 |
| A2 | 336 |
| A3 | 375 |

### Test Example 2

The silver-aluminum pastes for use on a front of an N-type double-sided solar cell B₁, B2 and B3 prepared in Examples 1-3 were printed on monocrystal substrates (156×156 mm, sheet resistance of 60 Ω/sq), dried and sintered to give crystalline silicon solar cells. The electrical properties of the cells were tested, and the results are averaged and listed in Table 4:

TABLE 4

| Number of | | | | | Fill | Conversion |
|---|---|---|---|---|---|---|
| silver-aluminum | Open-circuit | Short-circuit | Series | Parallel | factor | efficiency |
| paste | voltage (V) | current (A) | resistance | resistance | (%) | (%) |
| B1 | 0.6900 | 9.958 | 0.0021 | 2570 | 81.66 | 23.16 |
| B2 | 0.6880 | 9.960 | 0.0017 | 2658 | 81.97 | 23.26 |
| B3 | 0.6840 | 9.961 | 0.0019 | 2594 | 81.78 | 23.15 |

The present invention is not limited to the above-mentioned optimal embodiments, and any other various products may be obtained by anyone in light of the present invention. However, no matter what change in shape or structure thereof is made, all technical schemes that are identical or similar to those of the present invention will fall within the protection scope of the present invention.

1. A glass powder, comprising the following components by weight: 0-50% of PbO, 0-50% of BiO, 5-15% of B₂O₃, 8-9% of SiO₂, 2-3% of Al₂O₃ and 5-15% of ZnO, wherein the glass powder has a silicon-to-aluminum mass ratio of 4:1-5:1, and the glass powder further comprises 5-15% of an oxide of an element from group IA and 5-15% of an oxide of an element from group IIA.

2. The glass powder according to claim 1, wherein the oxide of the element from group IA is prepared from one or more compounds of the element from group IA selected from LiO, K₂O, Na₂O, Cs₂O, Li₂CO₃, K₂CO₃, NaCl and KCl.

3. The glass powder according to claim 1, wherein the oxide of the element from group IIA is prepared from one or more compounds of the element from group IIA selected from MgO, CaO, BaO, SrO, CaCO₃, MgCO₃ and BaCO₃.

4. The glass powder according to claim 1, wherein the glass powder has a softening temperature of 300-400° C. and an average particle size D₅₀ of 0.5-5 μm.

5. A silver-aluminum paste for use on a front of an N-type double-sided solar cell, comprising a conductive silver powder, a silicon-aluminum alloy powder, the glass powder according to claim 1 and an organic vehicle, wherein the conductive silver powder has a content of 80-90 wt % and comprises a nano-silver powder with an average particle size of 50-100 nm and a silver alloy powder with an average particle size of 1-10 μm; the nano-silver powder and the silver alloy powder have a mass ratio of 1:18-1:90; the glass powder has a content of 5-10 wt %.

6. The silver-aluminum paste for use on a front of an N-type double-sided solar cell according to claim 5, wherein the nano-silver powder has a purity of greater than 99%, an apparent density of 1.4-1.90 g/cm³ and a tap density of 2.6-4.1 g/cm³.

7. The silver-aluminum paste for use on the front of the N-type double-sided solar cell according to claim 5, wherein the aluminum-silicon alloy powder has a content of 1-10 wt %, an average particle size of 0.5-5 μm, a melting point of 450-650° C., and a Si mass fraction of 12-25%.

8. The silver-aluminum paste for use on the front of the N-type double-sided solar cell according to claim 6, wherein the aluminum-silicon alloy powder has a melting point of 500-600° C.; the aluminum-silicon alloy powder is at least one of an aluminum-silicon alloy powder having a Si mass fraction of 12%, an aluminum-silicon alloy powder having a Si mass fraction of 20% and an aluminum-silicon alloy powder having a Si mass fraction of 25%.

9. The silver-aluminum paste for use on the front of the N-type double-sided solar cell according to claim 5, wherein the organic vehicle has a content of 5-10 wt %; the organic vehicle comprises an organic binder, a surface dispersant and a thixotropic agent; the organic binder comprises 1-3 parts by mass of an organic resin and 7-9 parts by mass of an organic solvent; the organic resin is selected from one or more of ethyl cellulose and butyl cellulose acetate; the organic solvent is selected from one or more of terpineol, texanol, butyl carbitol, butyl carbitol acetate and glycerol; the surface dispersant is selected from one or more of stearic acid, a stearic acid derivative and an unsaturated fatty acid; the thixotropic agent is selected from one or more of a modified hydrogenated castor oil and a polyamide wax.

10. The silver-aluminum paste for use on the front of the N-type double-sided solar cell according to claim 8, wherein the silver-aluminum paste has a sintering temperature of 700-750° C.
